(19) United States
(12) Patent Application Publication
(10) Pub. No.: US 2024/0107812 A1
(43) Pub. Date: Mar. 28, 2024

(54) LIGHT EMITTING DISPLAY DEVICE

(71) Applicant: Samsung Display Co., Ltd., Yongin-Si (KR)

(72) Inventors: MINJOO KIM, Yongin-si (KR); Jun Won CHOI, Yongin-si (KR); Jun Young MIN, Yongin-si (KR); Min Woo BYUN, Yongin-si (KR); Jun-Yong AN, Yongin-si (KR); Chae Han HYUN, Yongin-si (KR); SUNGCHAN HWANG, Yongin-si (KR)

(21) Appl. No.: 18/226,027

(22) Filed: Jul. 25, 2023

(30) Foreign Application Priority Data
Sep. 22, 2022 (KR) 10-2022-0119993

(51) Int. Cl. H10K 59/121; G09G 3/3233; H10K 59/131

(52) U.S. Cl. CPC H10K 59/1216; G09G 3/3233; H10K 59/131; G09G 2300/0426; G09G 2300/0819; G09G 2300/0842; G09G 2300/0861; G09G 2310/08

(57) ABSTRACT

Provided is a light emitting display device comprising a driving transistor; a second transistor; a light emitting diode; a storage capacitor; a first scan line; and a driving gate electrode, in which a pixel includes only a transistor including an oxide semiconductor. The light emitting display device prevents deterioration of display quality due to a boost capacitor with a scan line in a pixel using an n-type transistor including an oxide semiconductor. Further, the light emitting display device prevents deterioration of display quality due to coupling with a data line in a pixel using an n-type transistor.

### CROSS-REFERENCE TO RELATED APPLICATION

This application claims priority to and the benefit of Korean Patent Application No. 10-2022-0119993 filed in the Korean Intellectual Property Office on Sep. 22, 2022, the entire contents of which are incorporated herein by reference.

### BACKGROUND

### 1. Field

The present disclosure generally relates to a light emitting display device, and more particularly, to a light emitting display device in which a pixel includes only a transistor including an oxide semiconductor.

### 2. Description of the Related Art

A display device is a device for displaying an image, and includes a liquid crystal display (LCD), an organic light emitting diode (OLED) display, which is a type of a light emitting display device, and the like. The display device is used in various electronic devices such as a mobile phone, a navigation device, a digital camera, an electronic book, a portable game machine, and various terminals.

A display device such as a light emitting display device may have a structure that may be bent or folded by using a flexible substrate.

A structure of a pixel used in the light emitting display device is being variously developed.

The above information disclosed in this Background section is only for enhancement of understanding of the background of the described technology, and therefore it may contain information that does not form the prior art that is already known in this country to a person of ordinary skill in the art.

### SUMMARY

Embodiments are to provide a light emitting display device that may prevent deterioration of display quality due to a boost capacitor with a scan line in a pixel using an n-type transistor including an oxide semiconductor.

Embodiments are to provide a light emitting display device that may prevent deterioration of display quality due to coupling with a data line in a pixel using an n-type transistor.

An embodiment provides a light emitting display device including: a driving transistor including a first gate electrode and a first semiconductor; a second transistor including a second gate electrode, and a second semiconductor having one end connected to a data line and the other end connected to the first gate electrode of the driving transistor; a light emitting diode including an anode; a storage capacitor including a first storage electrode connected to the anode of the light emitting diode and a second storage electrode overlapping the first storage electrode in a plan view; a first scan line connected to the second gate electrode of the second transistor; and a driving gate electrode connecting member connecting the second semiconductor of the second transistor, the second storage electrode, and the first gate electrode of the driving transistor, wherein the first scan line and the driving gate electrode connecting member cross and overlap in a plan view, and the first scan line and the driving gate electrode connecting member are positioned on a different layer from the first gate electrode, the second gate electrode, the first semiconductor, and the second semiconductor.

The first scan line and the driving gate electrode connecting member may cross and overlap in a plan view to configure a boost capacitor.

The light emitting display device may further include a hold capacitor including a first electrode and a second electrode, wherein the second electrode of the hold capacitor may be integral with the first storage electrode, and the first electrode of the hold capacitor and the first storage electrode may overlap in a plan view to configure the hold capacitor.

The first electrode of the hold capacitor may be connected to a driving voltage line or a reference voltage line.

The light emitting display device may further include a third transistor including a third gate electrode and a third semiconductor having one end connected to a reference voltage line and the other end connected to the second semiconductor, wherein the third semiconductor may be connected to the second storage electrode and the first gate electrode of the driving transistor through the driving gate electrode connecting member.

The light emitting display device may further include a fourth transistor including a fourth gate electrode, and a fourth semiconductor having one end connected to an initialization voltage line and the other end connected to the first storage electrode of the storage capacitor.

The initialization voltage line may be an initialization voltage line for a green pixel or an initialization voltage line for a red or blue pixel.

The light emitting display device may further include a fifth transistor including a fifth gate electrode and a fifth semiconductor having one end connected to a driving voltage line and the other end connected to the first semiconductor.

The light emitting display device may further include a shielding member extending from the fifth semiconductor and overlapping the data line, wherein the shielding member may be applied with a driving voltage.

The first semiconductor of the driving transistor may be integrally formed with the first storage electrode.

A first conductive layer including the first scan line and the second storage electrode may be positioned on a substrate; a first insulating film may be positioned on the first conductive layer; a semiconductor layer that includes the first semiconductor, the second semiconductor, and the first storage electrode and is formed of an oxide semiconductor, may be positioned on the first insulating film; a second insulating film may be positioned on the semiconductor layer; a second conductive layer including the first gate electrode and the second gate electrode may be positioned on the second insulating film; a third insulating film may be positioned on the second conductive layer; and a third conductive layer including the data line and the driving gate electrode connecting member may be positioned on the third insulating film.

The first gate electrode may not overlap the first storage electrode and the second storage electrode in a plan view.

Another embodiment provides a light emitting display device including: a driving transistor including a first gate electrode and a first semiconductor; a second transistor including a second gate electrode, and a second semiconductor having one end connected to a data line and the other end connected to the first gate electrode of the driving transistor; a light emitting diode including an anode; and a storage capacitor including a first storage electrode connected to the anode of the light emitting diode and a second storage electrode overlapping the first storage electrode in a plan view, wherein the first gate electrode does not overlap the first storage electrode or the second storage electrode in a plan view.

The light emitting display device may further include a hold capacitor including a first electrode and a second electrode, wherein the second electrode of the hold capacitor may be integral with the first storage electrode, the first electrode of the hold capacitor and the second storage electrode may overlap in a plan view, the first gate electrode may not overlap the first electrode of the hold capacitor in a plan view, and the first electrode of the hold capacitor may be connected to a driving voltage line or a reference voltage line.

The light emitting display device may further include a first scan line connected to the second gate electrode of the second transistor; and a driving gate electrode connecting member connecting the second semiconductor of the second transistor, the second storage electrode, and the first gate electrode of the driving transistor, wherein the first scan line and the driving gate electrode connecting member may cross and overlap in a plan view, and the first scan line and the driving gate electrode connecting member may be positioned on a different layer from the first gate electrode, the second gate electrode, the first semiconductor, and the second semiconductor.

The light emitting display device may further include a third transistor including a third gate electrode and a third semiconductor having one end connected to a reference voltage line and the other end connected to the second semiconductor, wherein the third semiconductor may be connected to the second storage electrode and the first gate electrode of the driving transistor through the driving gate electrode connecting member.

The light emitting display device may further include a fourth transistor including a fourth gate electrode, and a fourth semiconductor having one end connected to an initialization voltage line and the other end connected to the first storage electrode of the storage capacitor.

The initialization voltage line may be an initialization voltage line for a green pixel or an initialization voltage line for a red or blue pixel.

The light emitting display device may further include a fifth transistor including a fifth gate electrode and a fifth semiconductor having one end connected to a driving voltage line and the other end connected to the first semiconductor.

The light emitting display device may further include a shielding member extending from the fifth semiconductor and overlapping the data line, wherein the shielding member may be applied with a driving voltage.

According to the embodiments, a layer forming a boost capacitor while overlapping a scan line is not formed of an oxide semiconductor, so that even a size of the boost capacitor is not constant due to process dispersion of the oxide semiconductor, and by reducing the size of the boost capacitor, it is possible to prevent deterioration of display quality due to the boost capacitor.

According to the embodiments, it is possible to provide a light emitting display device in which display quality is not deteriorated by shielding coupling between a data line and a voltage line in a pixel of which a driving transistor is an n-type transistor.

### BRIEF DESCRIPTION OF THE DRAWINGS

FIG. 1 illustrates an equivalent circuit diagram of one pixel included in a light emitting display device according to an embodiment.

FIG. 2 illustrates a waveform diagram of various signals applied to the pixel of FIG. 1.

FIGS. 3, 4, 5, 6, 7, and 8 illustrate top plan views of each of layer according to a manufacturing sequence of the light emitting display device according to the embodiment of FIG. 1.

FIG. 9 shows elements involved in each layer in a summary according to FIGS. 3, 4, 5, 6, 7 and 8.

FIG. 10 illustrates a cross-sectional view of a light emitting display device according to an embodiment.

FIG. 11 illustrates an enlarged top plan view of a portion of a pixel of a light emitting display device.

FIG. 12 illustrates a cross-sectional view taken along line XI-XI′ of FIG. 11.

FIG. 13 illustrates a cross-sectional view taken along line XII-XII′ of FIG. 11.

FIG. 14 illustrates a circuit diagram of a position of a boost capacitor in the pixel of FIG. 1.

FIG. 15 illustrates an enlarged top plan view of a portion of a pixel of a light emitting display device according to a comparative example.

FIG. 16 illustrates a cross-sectional view taken along line XV-XV′ of FIG. 15.

FIG. 17 illustrates a graph comparing luminance distribution characteristics between comparative examples and a present embodiment.

### DETAILED DESCRIPTION

The present disclosure will be described more fully hereinafter with reference to the accompanying drawings, in which embodiments of the disclosure are shown.

As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, substrate, plate, or constituent element is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In addition, throughout the specification, “connected” does not only mean when two or more elements are directly connected, but when two or more elements are indirectly connected through other elements, and when they are physically connected or electrically connected, and further, it may be referred to by different names depending on a position or function, and may also be referred to as a case in which respective parts that are substantially integrated are linked to each other.

In addition, throughout the specification, when it is said that an element such as a wire, layer, film, region, area, substrate, plate, or constituent element “is extended (or extends) in a first direction or second direction”, this does not mean only a straight shape extending straight in the corresponding direction, but may mean a structure that substantially extends in the first direction or the second direction, is partially bent, has a zigzag structure, or extends while having a curved structure.

In addition, both an electronic device (for example, a mobile phone, a TV, a monitor, a laptop computer, etc.) including a display device, or a display panel described in the specification, and an electronic device including a display device and a display panel manufactured by a manufacturing method described in the specification are not excluded from the scope of the present specification.

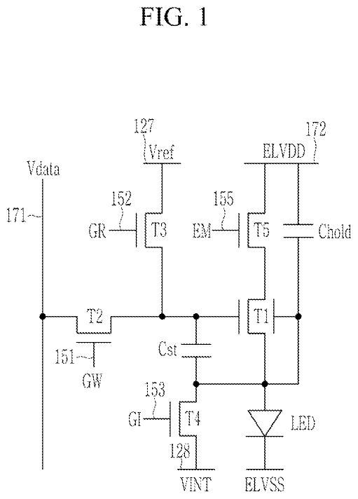

Firstly, a circuit structure of a pixel using an n-type transistor including an oxide semiconductor will be described with reference to FIG. 1.

FIG. 1 illustrates an equivalent circuit diagram of one pixel included in a light emitting display device according to an embodiment.

The pixel according to FIG. 1 includes a plurality of transistors T1, T2, T3, T4, and T5 connected to several wires 127, 128, 151, 152, 153, 155, 171, and 172, a storage capacitor Cst (hereinafter also referred to as a first capacitor), a hold capacitor Chold (hereinafter also referred to as a second capacitor), and a light emitting diode LED. Here, the transistors and the capacitors excluding the light emitting diode LED configure one pixel circuit part, and one pixel may include the pixel circuit part and the light emitting diode. In the embodiment of FIG. 1, the plurality of transistors T1, T2, T3, T4, and T5 may all be n-type transistors. In the present embodiment, the n-type transistor may be formed as an oxide semiconductor transistor including an oxide semiconductor. The n-type transistor may be a transistor that is turned on when a relatively high voltage of a gate electrode is applied.

The plurality of wires 127, 128, 151, 152, 153, 155, 171, and 172 are connected to one pixel PX. The plurality of wires includes a reference voltage line 127, an initialization voltage line 128, a first scan line 151, a second scan line 152, a third scan line 153, a light emitting control line 155, a data line 171, and a driving voltage line 172. Additionally, a common voltage line that transmits a driving low voltage ELVSS may be connected to one side of the light emitting diode LED.

The first scan line 151 transmits a first scan signal GW to a gate electrode of the second transistor T2, and the second scan line 152 transmits a second scan signal GR to a gate electrode of the third transistor T3. The third scan line 153 transmits a third scan signal GI to a gate electrode of the fourth transistor T4, and the light emitting control line 155 transmits a light emitting signal EM to a gate electrode of the fifth transistor T5.

The data line 171 is a line that transmits a data voltage Vdata generated by a data driver (not shown), and thus, as an amount of a light emitting current transmitted to the light emitting diode LED is changed, and luminance emitted by the light emitting diode LED is also changed. The driving voltage line 172 applies a driving voltage ELVDD. The reference voltage line 127 transmits a reference voltage Vref, and the initialization voltage line 128 transmits an initialization voltage VINT. In the present embodiment, each of voltages applied to the driving voltage line 172, the reference voltage line 127, and the initialization voltage line 128 may be a constant voltage.

The driving transistor T1 (also referred to as a first transistor) is an n-type transistor, and has an oxide semiconductor as a semiconductor layer. It is a transistor that adjusts the amount of the light emitting current outputted to one electrode (an anode) of the light emitting diode LED according to a voltage (that is, a voltage stored in the storage capacitor Cst) of a gate electrode (hereinafter also referred to as a driving gate electrode or a first driving gate electrode) of the driving transistor T1. An amount of a light emitting current outputted to one electrode (an anode) of the light emitting diode LED may be adjusted according to the data voltage Vdata applied to the pixel. For this purpose, a first electrode of the driving transistor T1 is disposed to receive the driving voltage ELVDD, and is connected to the driving voltage line 172 via the fifth transistor T5. Meanwhile, a second electrode of the driving transistor T1 outputs the light emitting current to the light emitting diode LED, and is connected to one electrode (the anode) of the light emitting diode LED. The data voltage Vdata is applied to the driving gate electrode of the driving transistor T1 through the second transistor T2. Meanwhile, the driving gate electrode of the driving transistor T1 is connected to one electrode of the storage capacitor Cst (hereinafter referred to as a “second storage electrode”). Accordingly, a voltage of the gate electrode of the driving transistor T1 is changed according to a voltage stored in the storage capacitor Cst, and accordingly, a light emitting current outputted from the driving transistor T1 is changed. The storage capacitor Cst serves to maintain the voltage of the gate electrode of the driving transistor T1 constant for one frame. Meanwhile, the driving gate electrode of the driving transistor T1 may also be connected to the third transistor T3 to be initialized by receiving the reference voltage Vref. Additionally, the driving transistor T1 may further include an overlapping electrode (hereinafter also referred to as a second driving gate electrode) overlapping a channel positioned in the semiconductor layer, and the overlapping electrode is connected to one electrode (the anode) of the light emitting diode LED, a second electrode of the fourth transistor T4, and a second electrode of the hold capacitor Chold. The overlapping electrode (the second driving gate electrode) is connected to one electrode (the anode) of the light emitting diode LED so that the characteristic of the driving transistor T1 may be maintained without being changed during a light emitting period.

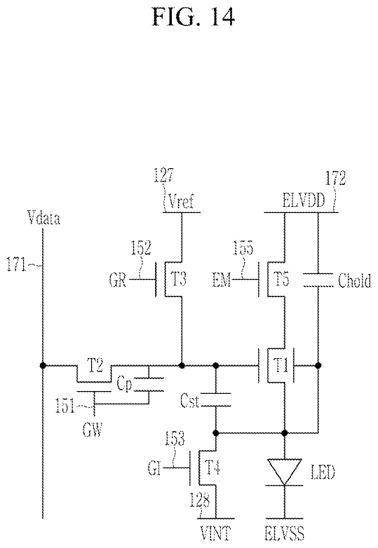

The second transistor T2 is an n-type transistor, and has an oxide semiconductor as a semiconductor layer. The second transistor T2 is a transistor that allows the data voltage Vdata to be received into the pixel. The gate electrode of the second transistor T2 is connected to the first scan line 151. A first electrode of the second transistor T2 is connected to data line 171, and a second electrode of the second transistor T2 is connected to the driving gate electrode of the driving transistor T1, a second electrode of the third transistor T3, and a second storage electrode of the storage capacitor Cst. When the second transistor T2 is turned on by a positive voltage of the first scan signal GW transmitted through the first scan line 151, the data voltage Vdata transmitted through the data line 171 is transmitted to the driving gate electrode of the driving transistor T1, and in this when the driving, the data voltage Vdata is stored in the second storage electrode of the storage capacitor Cst. Although not shown in FIG. 1, a boost capacitor (see Cp of FIG. 14), which is a type of parasitic capacitor, may be formed between the first scan line 151 and the driving gate electrode of the driving transistor T1 (or the second storage electrode of the storage capacitor Cst or a second electrode of the third transistor T3).

The third transistor T3 is an n-type transistor, and has an oxide semiconductor as a semiconductor layer. The third transistor T3 serves to transmit the reference voltage Vref to the driving gate electrode of the driving transistor T1 and the second storage electrode of the storage capacitor Cst. The gate electrode of the third transistor T3 is connected to the second scan line 152, and the first electrode of the third transistor T3 is connected to the reference voltage line 127. The second electrode of the third transistor T3 is connected to the second storage electrode of the storage capacitor Cst, the driving gate electrode of the driving transistor T1, and the second electrode of the second transistor T2. The third transistor T3 is turned on by a positive voltage of the second scan signal GR received through the second scan line 152, and in this case, it transmits the reference voltage Vref to the gate electrode of the driving transistor T1 and the second storage electrode of the storage capacitor Cst to initialize them.

The fourth transistor T4 is an n-type transistor, and has an oxide semiconductor as a semiconductor layer. The fourth transistor T4 serves to initialize one electrode (the anode) of the light emitting diode LED. Hereinafter, the fourth transistor T4 is also referred to as a light emitting diode initialization transistor. When the fourth transistor T4 initializes one electrode (the anode) of the light emitting diode LED, it also initializes the overlapping electrode (the second driving gate electrode) of the driving transistor T1, the first storage electrode of the storage capacitor Cst, and the second electrode of the hold capacitor Chold. The gate electrode of the fourth transistor T4 is connected to the third scan line 153, the second electrode of the fourth transistor T4 is connected one electrode of the light emitting diode LED, the overlapping electrode (the second driving gate electrode) of the driving transistor T1, the first storage electrode of the storage capacitor Cst, and the second electrode of the hold capacitor Chold, and the first electrode of the fourth transistor T4 is connected to the initialization voltage line 128. When the fourth transistor T4 is turned on by a positive voltage of the third scan signal GI flowing through the third scan line 153, it applies the initialization voltage VINT to one electrode of the light emitting diode LED, the overlapping electrode (the second driving gate electrode) of the driving transistor T1, the first storage electrode of the storage capacitor Cst, and the second electrode of the hold capacitor Chold to initialize them.

The fifth transistor T5 is an n-type transistor, and has an oxide semiconductor as a semiconductor layer. The fifth transistor T5 serves to transmit the driving voltage ELVDD to the first electrode of the driving transistor T1. The gate electrode of the fifth transistor T5 is connected to the light emitting control line 155, a first electrode of the fifth transistor T5 is connected to the driving voltage line 172, and a second electrode of the fifth transistor T5 is connected to the first electrode of the driving transistor T1. When the fifth transistor T5 is turned on by a positive voltage of the light emitting signal EM flowing through the light emitting control line 155, the driving voltage ELVDD is applied to the first electrode of the driving transistor T1.

In some embodiments, not only the driving transistor T1, but also the other transistors T2, T3, T4, and T5 may all have overlapping electrodes overlapping channels included in the semiconductor layer. In this case, in all the transistors T2, T3, T4, and T5 excluding the driving transistor T1, the overlapping electrode of each of them may be electrically connected to the gate electrode of each of thereof, and in this case, each overlapping electrode may serve as another gate electrode (hereinafter also referred to as a dual gate electrode).

In the above description, all transistors (T1, T2, T3, T4, and T5) are formed of n-type transistors, and an oxide semiconductor is used as the semiconductor layer, but any n-type transistor may be sufficient, and a silicon semiconductor may also be used for the semiconductor layer.

The first storage electrode of the storage capacitor Cst is connected to the second electrode of the fourth transistor T4, the second gate electrode of the driving transistor T1, the overlapping electrode (the second driving gate electrode) of the driving transistor T1, one electrode (the anode) of the light emitting diode LED, and the second electrode of the hold capacitor Chold, and the second storage electrode thereof is connected to the gate electrode of the driving transistor T1, the second electrode of the third transistor T3, and the second electrode of the second transistor T2. The storage capacitor Cst serves to maintain the voltage of the driving gate electrode of the driving transistor T1 constant for one frame.

The first electrode of the hold capacitor Chold is connected to the driving voltage line 172, and the second electrode of the hold capacitor Chold is connected to the overlapping electrode (the second driving gate electrode) of the driving transistor T1, the second electrode of the driving transistor T1, one electrode (the anode) of the light emitting diode LED, the second electrode of the fourth transistor T4, and the first storage electrode of the storage capacitor Cst. The hold capacitor Chold serves to maintain the voltage of the overlapping electrode (the second driving gate electrode) of the driving transistor T1 and the one electrode (the anode) of the light emitting diode LED constant, and particularly, it serves to maintain it constant during a light emitting period.

The pixel PX of FIG. 1 has been described as including five transistors T1 to T5 and two capacitors (the storage capacitor Cst and the hold capacitor Chold), but is not limited thereto, and as a parasitic capacitor, a boost capacitor (see Cp of FIG. 14) formed between the first scan line 151 and the driving gate electrode of the driving transistor T1 (or the second storage electrode of the storage capacitor Cst) may also be included.

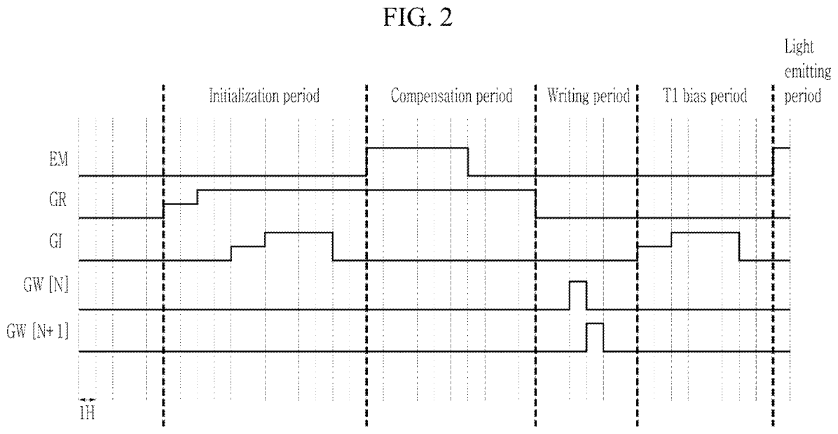

In the above, the circuit structure of the pixel according to the embodiment has been described with reference to FIG. 1. Hereinafter, a waveform of a signal applied to the pixel of FIG. 1 and an operation of the pixel according to the waveform will be described with reference to FIG. 2.

FIG. 2 illustrates a waveform diagram of various signals applied to the pixel of FIG. 1.

Referring to FIG. 2, when signals applied to a pixel is divided into periods, each of the signals may be divided into an initialization period, a compensation period, a writing period, and a light emitting period. In this case, a T1 bias period may be additionally included between the writing period and the light emitting period. Here, in the T1 bias period, even if no data voltage is transmitted during the writing period, a voltage relationship between respective electrodes of the driving transistor T1 is maintained so that the voltage relationship of the electrodes of the driving transistor T1 is not changed, so that it is possible to allow the driving transistor T1 to operate the same and to allow the light emitting display device to operate by various driving methods such as low power driving or high-speed driving. On the other hand, a gate-on voltage and a gate-off voltage may be a high voltage or a low voltage depending on a type of transistor to which they are applied, and in an n-type transistor, the high voltage may be the gate-on voltage and the low voltage may be the gate-off voltage. In FIG. 2, signal that increase twice when being changed from a low voltage to a high voltage are illustrated, but in some embodiments, signals may be changed to the highest high voltage at once.

Firstly, the light emitting period is a period in which the light emitting diode LED emits light, and in this period, the light emitting signal EM of the gate-on voltage is applied to turn on the fifth transistor T5. In this case, all other signals (the second scan signal GR, the third scan signal GI, and the first scan signal GW) have gate-off voltages. When the fifth transistor T5 is turned on and the driving voltage ELVDD is transmitted to the driving transistor T1, an output current is generated according to the voltage of the gate electrode of the driving transistor T1. In this case, it is a period in which the output current of the driving transistor T1 is transmitted to the light emitting diode LED so that the light emitting diode LED emits light. In addition, in the light emitting period, the overlapping electrode (the second driving gate electrode) of the driving transistor T1 and one electrode (the anode) of the light emitting diode LED are connected so that the characteristics of the driving transistor T1 that generates the output current may be constant. In FIG. 2, the light emitting period in which the light emitting signal EM of the gate-on voltage is applied is hardly illustrated, but the light emitting period actually has the longest time. However, in the light emitting period, only the above-described simple operation is performed, so since there is nothing to specifically explain, it is simply illustrated in FIG. 2.

After the light emitting period ends, the initialization period is entered. The light emitting period ends when the light emitting signal EM is changed to the gate-off voltage. Thereafter, as the second scan signal GR is changed to the gate-on voltage, the initialization period is entered, and thereafter, the third scan signal GI is also changed to the gate-on voltage during the light emitting period. In this case, the light emitting signal EM and the first scan signal GW are maintained at the gate-off voltage.

In the initialization period, the third transistor T3 to which the second scan signal GR is first applied is turned on. By the turned-on third transistor T3, the reference voltage Vref is transmitted to the driving gate electrode of the driving transistor T1 and the second storage electrode of the storage capacitor Cst, and they are initialized. Here, the reference voltage Vref may have a high voltage value capable of turning on the driving transistor T1.

Thereafter, the fourth transistor T4 to which the third scan signal GI is applied is turned on, and by the fourth transistor T4, the initialization voltage VINT is transmitted to one electrode (the anode) of the light emitting diode LED, the first storage electrode of the storage capacitor Cst, the second electrode of the hold capacitor Chold, the second electrode of the driving transistor T1, and the overlapping electrode (the second driving gate electrode) of the driving transistor T1 to be initialized.

Thereafter, after the third scan signal GI is changed to the gate-off voltage, as the light emitting signal EM is changed to the gate-on voltage, the compensation period is entered. In this case, the second scan signal GR is maintained at the gate-on voltage, and the first scan signal GW is maintained at the gate-off voltage.

The fifth transistor T5 is turned on by the light emitting signal EM, so that the driving voltage ELVDD is transmitted to the first electrode of the driving transistor T1. In the initialization period, since the voltage of the first storage electrode of the storage capacitor Cst is charged as the initialization voltage VINT and the driving transistor T1 is turned on by the reference voltage Vref, as the driving voltage ELVDD transmitted to the first electrode of the driving transistor T1 is transmitted to the first storage electrode of the storage capacitor Cst, the voltage of the first storage electrode increases. When the voltage of the first storage electrode increases and then is lower than the voltage of the driving gate electrode of the driving transistor T1 by the threshold voltage Vth, the driving transistor T1 is turned off, and the voltage at that time is stored in the first storage electrode of the storage capacitor Cst. Since the voltage of the driving gate electrode of the driving transistor T1 has the reference voltage Vref, the voltage value of the first storage electrode of the storage capacitor Cst at this time may be obtained by Equation 1 below.

Voltage of first storage electrode=Vref−Vth [Equation 1]

Referring to FIG. 1, since the first storage electrode and the overlapping electrode (the second driving gate electrode) of the driving transistor T1 are connected, the voltage value of the overlapping electrode (the second driving gate electrode) of the driving transistor T1 may be obtained by Equation 1.

Thereafter, after the light emitting signal EM is changed to the gate-off voltage, as the second scan signal GR is also changed to the gate-off voltage, the writing period is entered.

In the writing period, the first scan signal GW may be applied as a gate-on voltage for 1H, and the first scan signal GW of the gate-on voltage may be sequentially applied to the first scan line 151 of each row.

The second transistor T2 is turned on by the gate-on voltage of the first scan signal GW, and the data voltage Vdata is transmitted to the driving gate electrode of the driving transistor T1 and the second storage electrode of the storage capacitor Cst by the turned on second transistor T2. Since the voltage of the second storage electrode of the storage capacitor Cst is changed, the voltage of the first storage electrode of the storage capacitor Cst is also changed in proportion thereto.

More specifically, since the voltage of the second storage electrode of the storage capacitor Cst has the reference voltage Vref before entering the writing period and then is changed to the data voltage Vdata in the writing period, it is changed by a value obtained by subtracting the reference voltage Vref from the data voltage Vdata. Accordingly, the voltage of the first storage electrode of the storage capacitor Cst is maximally changed by the value obtained by subtracting the reference voltage Vref from the data voltage Vdata. Since the voltage of the first storage electrode of the storage capacitor Cst before entering the writing period is obtained by Equation 1, the voltage of the first storage electrode of the storage capacitor Cst after the writing period may be obtained by the following Equation 2.

Voltage of first storage electrode=Vref−Vth+α(Vdata−Vref) [Equation 2]

Thereafter, in FIG. 2, as the light emitting signal EM is changed to a gate-on voltage, the light emitting period is entered. In the light emitting period, the light emitting signal EM of the gate-on voltage is applied to turn on the fifth transistor T5, so that the driving voltage ELVDD is transmitted to the first electrode of the driving transistor T1, and the driving transistor T1 generates an output current.

The output current of the driving transistor T1 is determined according to a value obtained by subtracting the threshold voltage Vth from the level at which the voltage of the driving gate electrode is higher than the voltage of the second electrode of the driving transistor T1. Since the voltage value of Equation 2 is the same as the voltage value of the second electrode of the driving transistor T1 and the voltage value of the driving gate electrode is the same as the data voltage Vdata, the value of the output current is proportional to a value obtained by subtracting the voltage value of Equation 2 and the threshold voltage Vth from the data voltage Vdata. In summary, the output current value of the driving transistor T1 is obtained by Equation 3.

Output current=(1−α)(Vdata−Vref) [Equation 3]

Since Equation 3 is determined regardless of the threshold voltage Vth of the driving transistor T1, even if the threshold voltage Vth of each driving transistor T1 varies, the output current value is not affected, so that display quality is consistent.

Referring to FIG. 1, since the overlapping electrode (the second driving gate electrode) of the driving transistor T1 is also connected to the second electrode of the driving transistor T1, the channel characteristic of the driving transistor T1 may be maintained without being changed.

Meanwhile, referring to FIG. 2, the T1 bias period may proceed after the writing period ends, and in the T1 bias period, the third scan signal GI may be changed to the gate-on voltage at least once and then changed to the gate-off voltage again.

When the third scan signal GI is once applied as a high level voltage, the voltage of the overlapping electrode (the second driving gate electrode) of the driving transistor T1 is changed to the initialization voltage VINT. As a result, even if the voltage of the overlapping electrode (the second driving gate electrode) of the driving transistor T1 is changed due to leakage current and the like, it may be refreshed, and the voltages of the other electrodes (the driving gate electrode, the first electrode, and the second electrode) of the driving transistor T1 may also be refreshed, so that the characteristics of the driving transistor T1 may be prevented from being changed. In addition, in the T1 bias period, even if the data voltage Vdata is not applied in the writing period, the output current of the driving transistor T1 may be constantly maintained in the light emitting period by again raising the data voltage Vdata applied to the existing frame even if the data voltage Vdata applied to the existing frame is lowered. As a result, various driving methods such as low-power driving or high-speed driving of the light emitting display device may be enabled.

In some embodiments, the T1 bias period may be omitted in the driving method of the pixel. In addition, the driving method of the pixel according to the embodiment may include a first driving method in which the T1 bias period is included and a second driving method in which the T1 bias period is not included, and the first driving method may be operated in some periods, and the second driving method may be operated in the remaining periods.

In the above, the circuit structure and operation of the pixel have been described with reference to FIG. 1 and FIG. 2.

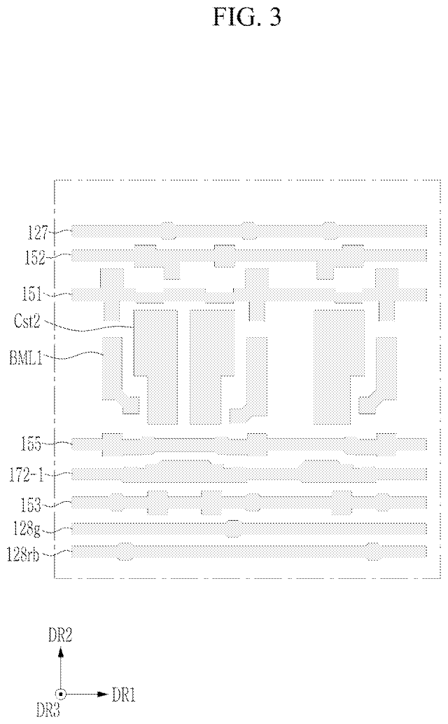

Hereinafter, a stacked structure of the pixel will be described in detail with reference to FIGS. 3, 4, 5, 6, 7, 8, and 9.

Firstly, a planar structure will be described with reference to FIG. 3 to FIG. 8.

FIGS. 3, 4, 5, 6, 7, and 8 illustrate top plan views of each of layers according to a manufacturing sequence of the light emitting display device according to the embodiment of FIG. 1.

The light emitting diode LED is not illustrated in FIGS. 3, 4, 5, 6, 7, and 8 below, but only a structure of a pixel circuit part positioned there below will be illustrated.

Referring to FIG. 3, a first conductive layer is positioned on a substrate 110 (not shown). The first conductive layer includes the reference voltage line 127, the second scan line 152, the first scan line 151, the light emitting control line 155, an additional driving voltage line 172-1, a third scan line 153, and initialization voltage lines 128g and 128rb which extend in a first direction DR1. The first conductive layer further include an overlapping electrode BML1 and a second storage electrode Cst2 having an island-like structure. Here, the initialization voltage lines 128g and 128rb include an initialization voltage line 128g for a green pixel and an initialization voltage line 128rb for a red or blue pixel as separate wires. The initialization voltage lines 128g and 128rb may apply different initialization voltages, and the initialization voltage for the green pixel and the initialization voltage for the red or blue pixel may have different voltage levels.

Here, the substrate 110 may include a material that has a rigid characteristic such as glass and thus is not bent, or may include a flexible material such as plastic or polyimide that may be bent. In a case of a flexible substrate, a two-layered structure that has polyimide and a barrier layer formed of an inorganic insulating material thereon may have a double structure.

The first conductive layer may include the following voltage lines extending in the first direction DR1.

The reference voltage line 127 transmits the reference voltage Vref in the first direction DR1, the second scan line 152 transmits the second scan signal GR in the first direction DR1, the first scan line 151 transmits the first scan signal GW in the first direction DR1, the light emitting control line 155 transmits the light emitting signal EM in the first direction DR1, the additional driving voltage line 172-1 transmits the driving voltage ELVDD in the first direction DR1, the third scan line 153 transmits the third scan signal GI in the first direction DR1, and the initialization voltage lines 128g and 128rb respectively transmit the initialization voltage VINT in the first direction DR1. The scan lines 151, 152, and 153 and the light emitting control line 155 may further include a portion protruding in a second direction DR2.

In addition, the overlapping electrode BML1 may also serve as a dual gate electrode of the driving transistor T1, and may overlap the channel and the driving gate electrode of the driving transistor T1 which are subsequently formed in a plan view. Meanwhile, the second storage electrode Cst2 may overlap a subsequent conductive layer to form the storage capacitor Cst.

The first conductive layer may include a metal such as copper (Cu), molybdenum (Mo), aluminum (Al), or titanium (Ti) or a metal alloy thereof, and may be formed as a single layer or a multilayer.

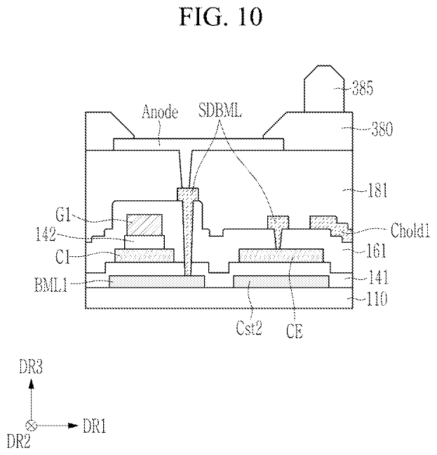

Referring to FIG. 10, a first insulating film 141 may be disposed on the substrate 110 and the first conductive layer which includes the overlapping electrode BML1 and the second storage electrode Cst2. The first insulating film 141 may be an inorganic insulating film including a silicon oxide (SiOx), a silicon nitride (SiNx), or a silicon oxynitride (SiOxNy).

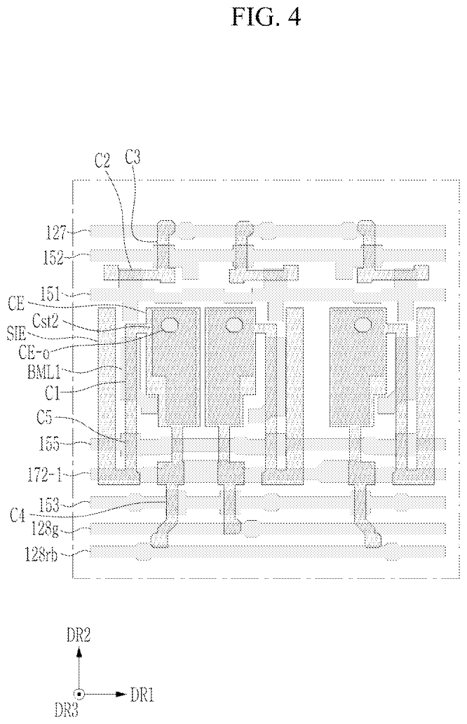

Referring to FIG. 4, a semiconductor layer is positioned on the first insulating film 141 (not shown), and the semiconductor layer includes a capacitor electrode CE and a fourth semiconductor C4 extending downward from the capacitor electrode CE, and also includes a first semiconductor C1 and a fifth semiconductor C5 that are connected to each other in the first direction DR1 or a direction opposite to the first direction DR1. Meanwhile, the semiconductor layer is separated from the capacitor electrode CE, and includes the second semiconductor C2 and the third semiconductor C3 connected to each other. The semiconductor layer may be formed of an oxide semiconductor. The capacitor electrode CE may be integrally formed with the first semiconductor C1, a fourth semiconductor C4, and a fifth semiconductor C5.

An opening CE-o may be defined in the capacitor electrode CE, and may have a structure extending in the second direction DR2. Here, the capacitor electrode CE may serve as the first storage electrode of the storage capacitor Cst and the second electrode of the hold capacitor Chold.

The capacitor electrode CE is connected to the fourth semiconductor C4 protruding in the second direction DR2. In addition, the capacitor electrode CE protrudes in the first direction DR1 or in a direction opposite to the first direction DR1 to be connected to the first semiconductor C1, the first semiconductor C1 further extends in the second direction DR2 and overlaps the fifth semiconductor C5, and the fifth semiconductor C5 is connected to a shielding member SIE extending in the second direction DR2 after being bent.

The second semiconductor C2 and the third semiconductor C3 are connected to each other. That is, the second semiconductor C2 extends in the first direction DR1, and is connected to a third semiconductor C3 by being bent in the second direction DR2. The third semiconductor C3 is extended in the second direction DR2.

Referring to FIG. 10, a second insulating film 142 is disposed on the semiconductor layer. The second insulating film 142 may be an inorganic insulating film including a silicon oxide (SiOx), a silicon nitride (SiNx), or a silicon oxynitride (SiOxNy). In FIG. 10, the second insulating layer 142 is shown to be positioned only in a partial area, but in some embodiments, it may be stacked as a whole like the first insulating film 141.

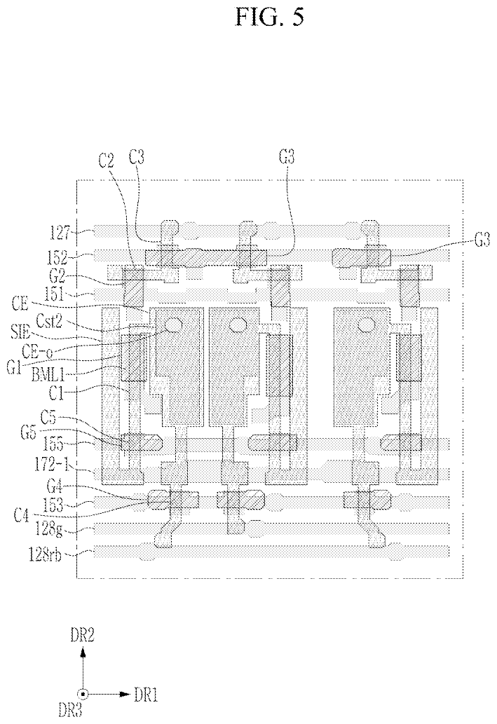

Referring to FIG. 5, a second conductive layer is positioned on the second insulating film 142 (not shown) The second conductive layer includes a first gate electrode G1 (also referred to as a driving gate electrode), a second gate electrode G2, a third gate electrode G3, a fourth gate electrode G4, and a fifth gate electrode G5, which have an island-like structure.

The first gate electrode G1 (driving gate electrode) overlaps the first semiconductor C1 and the overlapping electrode BML1 in a plan view. The second gate electrode G2 is positioned at a portion overlapping the second semiconductor C2 and the first scan line 151 in a plan view, and the third gate electrode G3 is positioned at a portion overlapping the third semiconductor C3 and the second scan line 152 in a plan view. The fourth gate electrode G4 is positioned at a portion overlapping the fourth semiconductor C4 and the third scan line 153 in a plan view, and the fifth gate electrode G5 is positioned at a portion overlapping the fifth semiconductor C5 and the light emitting control line 155 in a plan view.

The second conductive layer may include a metal such as copper (Cu), molybdenum (Mo), aluminum (Al), or titanium (Ti), or a metal alloy thereof, and may be formed as a single layer or a multilayer.

After the second conductive layer is processed, the semiconductor layer that is not covered by the second conductive layer is doped through plasma treatment or doping treatment to have a conductivity characteristic similar to that of a conductor. As a result, the semiconductor layer that is not covered with each gate electrode becomes a conductor to electrically connect adjacent transistors. In addition, the capacitor electrode CE positioned on the semiconductor layer is also doped to have the same conductive characteristics as a conductor, so that it may serve as the first storage electrode of the storage capacitor Cst and the second electrode of the hold capacitor Chold. In addition, the shielding member SIE is also doped to have the same conductive characteristics as a conductor, so that it may serve as a shielding electrode.

In the structure described above, the structure of each of the transistors T1, T2, T3, T4, and T5 and each of the capacitors Cst and Chold may be summarized as follows.

The driving transistor T1 includes the first gate electrode G1 and the first semiconductor C1, and the second transistor T2 includes the second gate electrode G2 and the second semiconductor C2 in which one end thereof is connected to the data line 171 and the other end thereof is connected to the first gate electrode G1 of the driving transistor T1.

The third transistor T3 includes the third gate electrode G3, and the third semiconductor C3 in which one end thereof is connected to the reference voltage line 127 and the other end thereof is connected to the second semiconductor C2.

The fourth transistor T4 includes the fourth gate electrode G4, and the fourth semiconductor in which one end thereof is connected to the initialization voltage lines 128g and 128rb and the other end thereof is connected to the capacitor electrode CE. Here, the initialization voltage lines 128g and 128rb may be the initialization voltage line 128g for the green pixel or the initialization voltage line 128rb for the red or blue pixel.

The fifth transistor T5 includes the fifth gate electrode T5, and the fifth semiconductor C5 in which one end thereof is connected to the driving voltage lines 172 and 172-1 and the other end thereof is connected to the first semiconductor C1. Here, the fifth semiconductor C5 may configure the shielding member SIE that extends to overlap the data line 171.

The storage capacitor Cst includes the second storage electrode Cst2 and the capacitor electrode CE overlapping the second storage electrode Cst2 in a plan view, and the capacitor electrode CE serves as the first storage electrode.

The hold capacitor Chold includes the first electrode Chold1, and the capacitor electrode CE that overlaps the first electrode Chold1 in a plan view and serves as the second electrode. Here, both the second electrode of the hold capacitor Chold and the first storage electrode of the storage capacitor Cst may be integrally formed as the capacitor electrode CE.

Referring to FIG. 10, the second insulating film 142 and the second conductive layer are entirely covered by the third insulating film 161. The third insulating film 161 may be an inorganic insulating film including a silicon oxide (SiOx), a silicon nitride (SiNx), or a silicon oxynitride (SiOxNy). In some embodiments, the third insulating film 161 may be formed as an organic insulating film.

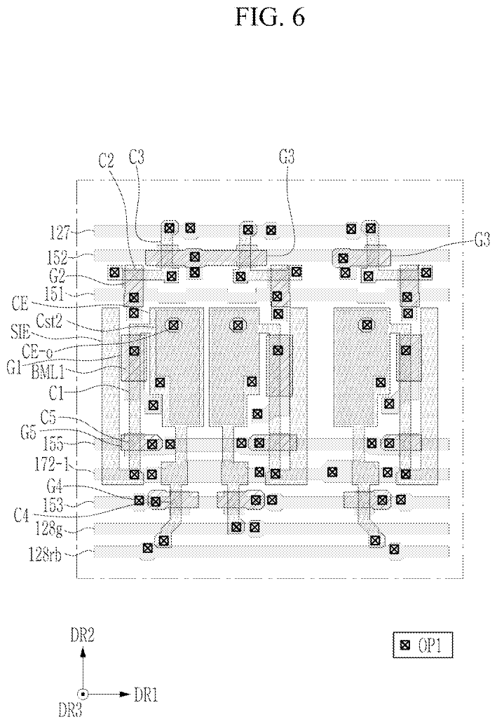

Referring to FIG. 6, a plurality of openings OP1 are formed in the third insulating film 161. The plurality of openings OP1 allow a subsequently formed third conductive layer to be connected to the second conductive layer, the semiconductor layer, and the first conductive layer that are positioned thereunder.

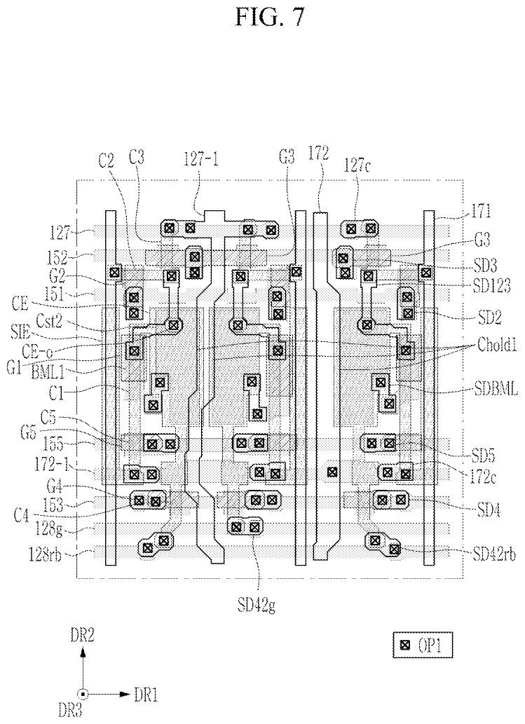

Referring to FIG. 7, the third conductive layer is formed on the third insulating film 161 (not shown), and the third conductive layer includes the data line 171, the driving voltage line 172, and an additional reference voltage line 127-1 that extends in the second direction DR2, and additionally includes a plurality of connecting members SD123, SD2, SD3, SDBML, SD5, SD4, SD42g, SD42rb, 172c, and 127c having an island-like structure.

The data line 171 is connected to the second semiconductor C2 through the opening OP1 to transmit the data voltage Vdata to the second semiconductor C2. The data line 171 overlaps the shielding member SIE, and the shielding member SIE is positioned under the data line 171 and serves to shield the voltages of other portions included in the pixel from being changed even if the data voltage applied to the data line 171 is changed. As a result, even if the data voltage Vdata flowing through the data line 171 is changed, the voltages of other portions of the pixel are not affected by the shielding member SIE to which the driving voltage ELVDD is applied. As a result, the voltage is not changed according to the swing of the data voltage Vdata in each pixel, and there is no problem in display quality.

The driving voltage line 172 is connected to the additional driving voltage line 172-1 through the opening OP1, so that the driving voltage ELVDD is transmitted in the first direction DR1 through the additional driving voltage line 172-1, and is transmitted in the second direction DR2 through the driving voltage line 172. As a result, the voltage level difference of the driving voltage ELVDD does not occur according to the position. In addition, the additional driving voltage line 172-1 is connected to the fifth semiconductor C5 by the connecting member 172c to transmit the driving voltage ELVDD to the fifth semiconductor C5 and the shielding member SIE.

Meanwhile, the driving voltage line 172 protrudes in the first direction DR1 to overlap the capacitor electrode CE in a plan view, and a portion Chold1 of the driving voltage line 172 overlapping the capacitor electrode CE in a plan view may serve as the first electrode of the hold capacitor Chold. That is, the driving voltage line 172 and the capacitor electrode CE may overlap in a plan view to form the hold capacitor Chold. In this case, the capacitor electrode CE may serve as the second electrode of the hold capacitor Chold.

In some embodiments, the common voltage line transmitting the driving low voltage ELVSS may be positioned at a position of the driving voltage line 172, and the common voltage line and the driving voltage line 172 may be alternately positioned.

The additional reference voltage line 127-1 is connected to the reference voltage line 127 through the opening OP1, the reference voltage Vref is transmitted to the first direction DR1 through the reference voltage line 127, and is transmitted in the second direction DR2 through the additional reference voltage line 127-1 so that the voltage of the reference voltage Vref does not differ depending on the position.

Meanwhile, the additional reference voltage line 127-1 protrudes in the first direction DR1 to overlap the capacitor electrode CE in a plan view, and a portion Chold1 of the additional reference voltage line 127-1 overlapping the capacitor electrode CE in a plan view may serve as the first electrode of the hold capacitor Chold. That is, the additional reference voltage line 127-1 and the capacitor electrode CE may overlap in a plan view to form the hold capacitor Chold. In this case, the capacitor electrode CE may serve as the second electrode of the hold capacitor Chold.

A portion of the additional reference voltage line 127-1 extending in the first direction DR1 or the connecting member 127c is connected to the third semiconductor C3 through the opening OP1 to transmit the reference voltage Vref to the third semiconductor C3.

Meanwhile, in some embodiments, an additional initialization voltage line to which the initialization voltage VINT is applied may be positioned at the position of the additional reference voltage line 127-1 to be connected to one of the initialization voltage lines 128g and 128rb, and the initialization voltage VINT is transmitted in the first direction DR1 and the second direction DR2 so that the initialization voltage VINT does not change the voltage according to the position. In some embodiments, the additional reference voltage line 127-1, the additional initialization voltage line for the green, and the additional initialization voltage line for the red or blue may be alternately positioned.

Accordingly, the first electrode Chold1 of the hold capacitor Chold may be a portion Chold1 of the driving voltage line 172 overlapping the capacitor electrode CE in a plan view or a portion Chold1 of the additional reference voltage line 127-1 overlapping the capacitor electrode CE in a plan view according to the portion thereof. Therefore, the first electrode Chold1 of the hold capacitor Chold may be connected to the driving voltage line 172 to which the driving voltage ELVDD is applied, but unlike FIG. 1, it may be connected to the reference voltage line (or the additional reference voltage line 127-1) to which the reference voltage Vref is applied. In addition, depending on the position thereof, the first electrode Chold1 of the hold capacitor Chold may be connected to one of the common voltage line transmitting the driving low voltage ELVSS, the additional initialization voltage line for the green, and the additional initialization voltage line for the red or blue.

The connecting member SD123 (hereinafter also referred to as a driving gate electrode connecting member) has a structure extending in the second direction DR2, bent in the first direction DR1, and then extending in the second direction DR; and one end thereof is connected to the second semiconductor C2 and the third semiconductor C3 through the opening OP1, is connected to the second storage electrode Cst2 through another opening OP1, and is connected to the first gate electrode G1 (the driving gate electrode) through the other opening OP1. When the connecting member SD123 is connected to the second storage electrode Cst2, it is connected to the second storage electrode Cst2 through the opening CE-o of the capacitor electrode CE.

The connecting member SDBML extends in the second direction DR2, and one end thereof is connected to the capacitor electrode CE through the opening OP1, and is connected to the overlapping electrode BML1 through another opening OP1.

The connecting member SD2 extends in the second direction DR2, and one end thereof is connected to the second gate electrode G2 through the opening OP1, and is connected to the first scan line 151 through another opening OP1.

The connecting member SD3 extends in the second direction DR2, and one end thereof is connected to the third gate electrode G3 through the opening OP1, and is connected to the second scan line 152 through another opening OP1.

The connecting member SD4 extends in the first direction DR1, and one end thereof is connected to the fourth gate electrode G4 through the opening OP1, and is connected to the third scan line 153 through another opening OP1.

The connecting member SD5 extends in the first direction DR1, and one end thereof is connected to the fifth gate electrode G5 through the opening OP1, and is connected to the light emitting control line 155 through another opening OP1.

The connecting members SD42g and SD42rb extend in the second direction DR2, respectively, and one ends are connected to the fourth semiconductor C4 through the opening OP1, and are connected to the initialization voltage lines 128g and 128rb through another opening OP1, respectively.

The third conductive layer may include a metal such as copper (Cu), molybdenum (Mo), aluminum (Al), or titanium (Ti), or a metal alloy thereof, and may be formed as a single layer or a multilayer.

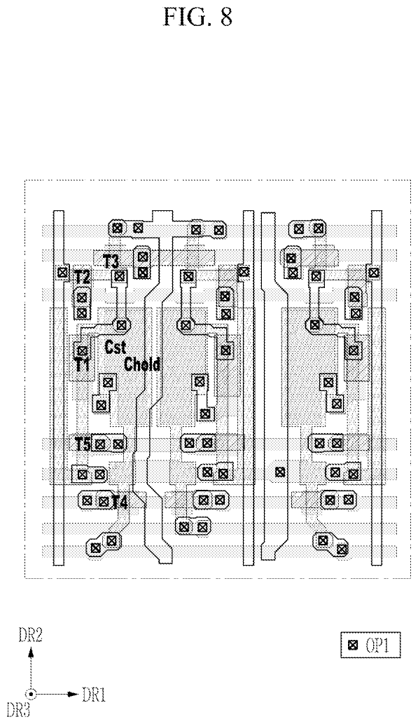

Referring to FIG. 8, the positions of the transistors T1, T2, T3, T4, and T5 and the positions of the storage capacitor Cst and the hold capacitor Chold are clearly shown so that the top plan views of FIGS. 3, 4, 5, 6, and 7, and the circuit structure of FIG. 1 may be more easily understood.

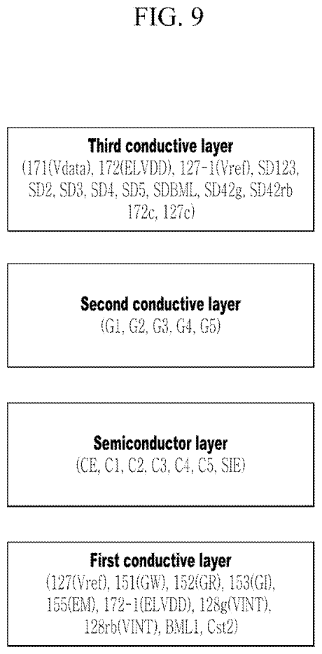

FIG. 9 shows elements involved in each layer in a summary according to FIGS. 3, 4, 5, 6, 7 and 8.

Referring to FIG. 9, each of the first conductive layer, the semiconductor layer, the second conductive layer, and the third conductive layer may involve each elements mentioned in the corresponding box. In FIG. 9, because some elements transmit a signal or a voltage, some elements also have a name of a signal or a voltage with parentheses.

Hereinafter, a cross-sectional structure of a light emitting display device will be described with reference to FIG. 10.

FIG. 10 illustrates a cross-sectional view of a light emitting display device according to an embodiment.

Referring to FIG. 10, the second storage electrode Cst2 and the overlapping electrode BML1 included in the first conductive layer are formed on the substrate 110. Further, the first insulating film 141 is disposed on the first conductive layer, the semiconductor layer is positioned on the first insulating film 141. In this case, FIG. 10 illustrates the capacitor electrode CE and the first semiconductor C1 included in the semiconductor layer. The capacitor electrode CE overlaps the second storage electrode Cst2 to configure the storage capacitor Cst, and in this case, the capacitor electrode CE may be the first storage electrode.

The second insulating film 142 is positioned on the semiconductor layer, and the first gate electrode G1 (the driving gate electrode) included in the second conductive layer is shown on the second insulating film 142. Here, the second insulating film 142 may have substantially the same width as the first gate electrode G1 (the driving gate electrode), and when the first gate electrode G1 (the driving gate electrode) is etched, the second insulating film 142 is also etched, so that the second insulating film 142 is formed to be positioned only under the first gate electrode G1 (the driving gate electrode). However, in some embodiments, the second insulating film 142 may be entirely formed.

The third insulating film 161 is covered on the second conductive layer, and the opening is positioned in at least some of the third insulating film 161, the second insulating film 142, and the first insulating film 141.

The opening positioned in the third insulating film 161 exposes the capacitor electrode CE, and the opening OP1 positioned in the third insulating film 161, the second insulating film 142, and the first insulating film 141 exposes the overlapping electrode BML1.

On the third insulating film 161, the connecting member SDBML and the first electrode Chold1 of the hold capacitor Chold included in the third conductive layer are positioned. The overlapping electrode BML1 and the capacitor electrode CE are connected by the connecting member SDBML, and the first electrode Chold1 of the hold capacitor Chold at least partially overlaps the capacitor electrode CE to configure the hold capacitor Chold. Here, the capacitor electrode CE may be the second electrode of the hold capacitor Chold.

In the above embodiment, only one manufacturing step for openings OP1 is involved so that respective constituent elements are electrically connected.

However, in some embodiments, respective constituent elements may be electrically connected in various ways. In this case, some connecting members may be removed from the third conductive layer.

Referring to FIG. 10, an organic film 181 may be positioned on the third conductive layer, and an anode (Anode), which is one electrode of the light emitting diode LED, may be positioned on the organic film 181. The anode (Anode) of the light emitting diode LED is electrically connected to the capacitor electrode CE by the connecting member SDBML to receive the output current of the driving transistor Ti. The structure of one electrode (the anode) of the light emitting diode LED may be various; a pixel defining film 380 having an opening exposing a portion of one electrode (the anode) of the light emitting diode LED, a light emitting layer (not shown) positioned in the opening, a spacer 385 positioned on the pixel defining film 380, and the other electrode (a cathode; not shown) of the light emitting diode LED positioned on the pixel defining film 380, the spacer 385, and the light emitting layer may be further included; and an encapsulation layer (not shown) may be positioned thereon. Here, the encapsulation layer includes at least one inorganic layer and at least one organic layer, and in some embodiments, it may have a triple-layered structure including a first inorganic encapsulation layer, an organic encapsulation layer, and a second inorganic encapsulation layer. The encapsulation layer may be for protecting the light emitting layer from moisture or oxygen that may be introduced from the outside. In some embodiments, the encapsulation layer may have a structure in which an inorganic layer and an organic layer are sequentially further stacked.

In addition, in some embodiments, a configuration that enables touch sensing may be further included on the encapsulation layer, and in some embodiments, a configuration such as a light blocking member or a color filter may be further included. In some embodiments, a color converting layer including quantum dots may be included instead of a color filter, or a reflective adjustment layer may be included.

Referring to FIGS. 10, 11, 12, 13, 14, 15, and 16, the characteristics of the present embodiment as described above will be described in comparison with a comparative example.

Firstly, FIGS. 10, 11, 12, and 13 illustrate a portion corresponding to a boost capacitor among pixels of the present embodiment.

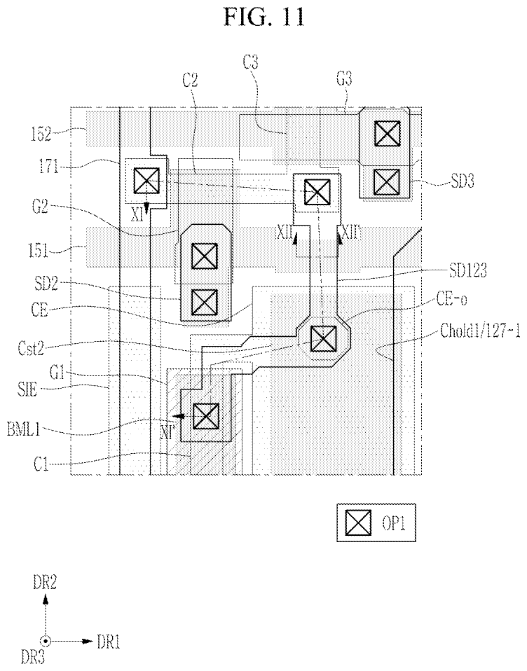

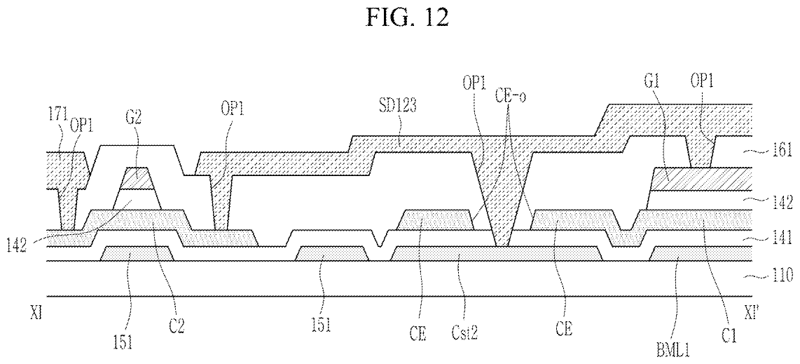

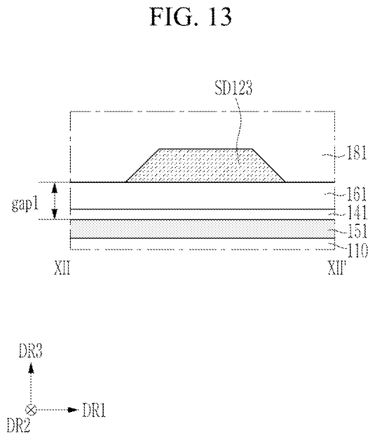

FIG. 11 illustrates an enlarged top plan view of a portion of a pixel of a light emitting display device, FIG. 12 illustrates a cross-sectional view taken along line XI-XI′ of FIG. 11, FIG. 13 illustrates a cross-sectional view taken along line XII-XII′ of FIG. 11, and FIG. 14 illustrates a circuit diagram of a position of a boost capacitor in the pixel of FIG. 1.

FIG. 11 illustrates an enlarged view of a portion adjacent to the second direction DR2 centered on the first scan line 151, and FIG. 12 illustrates in more detail a connection structure of the second transistor T2, the storage capacitor Cst, and the driving transistor T1 centered on the connecting member SD123.

Specifically, the second scan line 152 extending in the first direction DR1 is positioned at the second direction DR2 side of the first scan line 151 extending in the first direction DR1, and a portion of the second storage electrode Cst2 and a portion of the overlapping electrode BML1 are positioned at the opposite side of the first scan line 151 in the second direction DR2.

The third semiconductor C3, the third gate electrode G3, and the connecting member SD3 are positioned in a portion overlapping the second scan line 152, and the third gate electrode G3 and the second scan line 152 are connected by the connecting member SD3. The third gate electrode G3 crosses and overlaps the third semiconductor C3 to configure the third transistor T3.

Meanwhile, the second semiconductor C2, the second gate electrode G2, and the connecting member SD2 are positioned in a portion overlapping the first scan line 151, and the second gate electrode G2 and the first scan line 151 are connected by the connecting member SD2. The second gate electrode G2 crosses and overlaps the second semiconductor C2 to configure the second transistor T2.

The second semiconductor C2 extends in the first direction DR1, and the third semiconductor C3 extends in the second direction DR2, and they meet each other. The end of the connecting member SD123 is connected to the portion where the second semiconductor C2 and the third semiconductor C3 meet.

Meanwhile, the data line 171 is connected to the other end of the second semiconductor C2. The data line 171 overlaps and is shielded with the shielding member SIE positioned on the first conductive layer, so that the voltage of each portion of the pixel does not fluctuate according to the swing of the data voltage Vdata, and there is no problem in display quality.

The second semiconductor C2 and the third semiconductor C3 are connected to the second storage electrode Cst2 positioned on the first conductive layer and the first gate electrode G1 (the driving gate electrode) positioned on the second conductive layer by the connecting member SD123. Referring to FIG. 12, it can be clearly seen that the second semiconductor C2, the second storage electrode Cst2, and the first gate electrode GI (the driving gate electrode) are connected by the connecting member SD123. In addition, referring to FIG. 11, since the connecting member SD123 is connected to a portion where the second semiconductor C2 and the third semiconductor C3 are connected, the third semiconductor C3 is also connected to the second storage electrode Cst2 and the first gate electrode GI (the driving gate electrode) by the connecting member SD123.

As a result, the connecting member SD123 is the same node as the first gate electrode G1 of the driving transistor T1 and may have the same voltage as it.

The second storage electrode Cst2 overlaps the capacitor electrode CE positioned on the semiconductor layer, and the capacitor electrode CE overlaps the driving voltage line 172 (referring to FIG. 7) or the additional reference voltage line 127-1 positioned on the third conductive layer. As a result, the second storage electrode Cst2 and the capacitor electrode CE configure the storage capacitor Cst, and the capacitor electrode CE and the driving voltage line 172 or the additional reference voltage line 127-1 configure the hold capacitor Chold. Here, the capacitor electrode CE may serve as the first storage electrode of the storage capacitor Cst and the second electrode of the hold capacitor Chold. In some embodiments, the voltage line overlapping the capacitor electrode CE to configure the hold capacitor Chold may be a voltage line other than the driving voltage line 172 or the additional reference voltage line 127-1 (for example, the common voltage line or the initialization voltage line).

An opening CE-o is defined in the capacitor electrode CE, so that the connecting member SD123 may be connected to the second storage electrode Cst2 positioned below the capacitor electrode CE.

Meanwhile, the capacitor electrode CE is connected to the first semiconductor C1, and the first semiconductor C1 overlaps the overlapping electrode BML1 positioned on the first conductive layer and the first gate electrode G1 (the driving gate electrode) positioned on the second conductive layer. The first semiconductor C1 and the first gate electrode G1 (the driving gate electrode) configure the driving transistor T1, and the overlapping electrode BML1 may serve as a dual gate electrode of the driving transistor Ti.

In the structure of FIG. 11 as described above, the cross-sectional structure of a portion at which the cross-sectional line XI-XI′ is positioned, that is, of a portion at which the first scan line 151 and the connecting member SD123 cross and overlap to form a boost capacitor, which is a parasitic capacitor, is shown in FIG. 13. In addition, when the boost capacitor is shown in a circuit diagram, it may be as shown in FIG. 14.

Referring to FIG. 13, the first scan line 151 and the connecting member SD123 are formed of the first conductive layer and the third conductive layer, respectively, and are configured to be a conductive layer positioned the farthest. In addition, the first insulating film 141 and the third insulating film 161 are positioned between the first scan line 151 and the connecting member SD123, so that the first scan line 151 and the connecting member SD123 are positioned with a first gap (gap1) therebetween. Accordingly, a boost capacitor (see Cp in FIG. 14), which is a parasitic capacitor according to the present embodiment, is formed to have the smallest possible capacitance. As a result, the pixel may be least affected by the boost capacitor (see Cp in FIG. 14).

As shown in FIG. 2, the portion overlapping the second scan line 152, the third scan line 153, and the light emitting control line 155 changes the voltage of the electrode overlapping the second scan signal GR, the third scan signal GI, and the light emitting signal EM while they are changed, and forms a parasitic capacitor. However, since they are not connected to the first gate electrode G1 (the driving gate electrode) of the driving transistor T1, the voltage fluctuation has little meaning. However, since the first scan line 151 overlaps the connecting member SD123 and the connecting member SD123 is connected to the first gate electrode G1 (the driving gate electrode) of the driving transistor T1, the output current generated by the driving transistor T1 is affected. Therefore, in the present embodiment, since the capacitance of the boost capacitor (see Cp in FIG. 14) is formed to be the smallest, the influence of the voltage of the first gate electrode G1 (the driving gate electrode) of the driving transistor T1 is minimal due to the first scan signal GW applied to the first scan line 151. Accordingly, there is no change in display quality due to the first scan signal GW.

In addition, no oxide semiconductor is included in the boost capacitor Cp of the present embodiment. Unlike the conductive layer during the process, the oxide semiconductor has a large dispersion according to the process, so the width or size of the actually manufactured oxide semiconductor may vary depending on the position thereof. Therefore, when the boost capacitor Cp includes the oxide semiconductor layer, the overlapping area of the boost capacitor Cp may also be different for each pixel, thereby causing a difference in luminance displayed in each pixel, so a stain may be viewed by the user's eyes. However, in the present embodiment, the oxide semiconductor is not included in the boost capacitor Cp, and the first conductive layer and the third conductive layer are formed, so there is no display quality problem due to the size difference of the boost capacitor Cp.

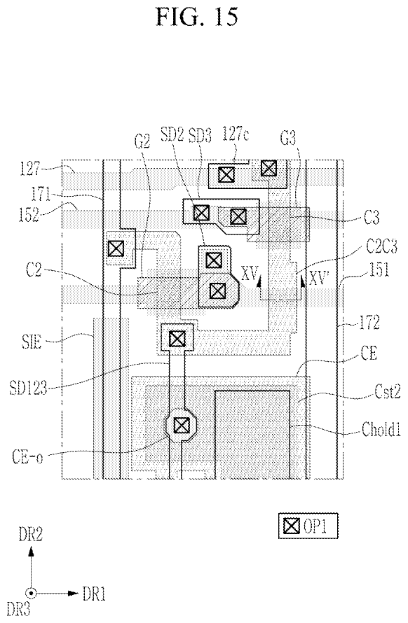

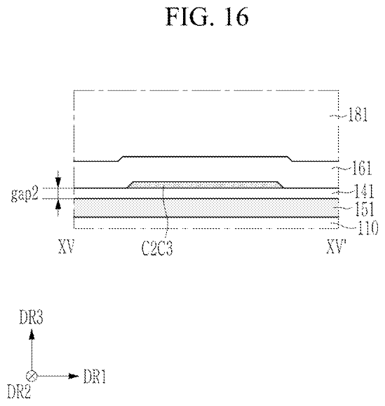

Hereinafter, a portion corresponding to a boost capacitor Cp of a pixel of a comparative example will be described with reference to FIG. 15 and FIG. 16.

FIG. 15 illustrates an enlarged top plan view of a portion of a pixel of a light emitting display device according to a comparative example, and FIG. 16 illustrates a cross-sectional view taken along line XV-XV′ of FIG. 15.

Although only a portion of the comparative example is shown in FIG. 15 and FIG. 16, the comparative example of FIG. 15 and FIG. 16 also has the same circuit configuration as in FIG. 1.

Referring to FIG. 15 and FIG. 16, in the comparative example, there is a portion in which a connecting portion C2C3 to which the second semiconductor C2 and the third semiconductor C3 are connected overlaps the first scan line 151 in a plan view, and in FIG. 15, a boost capacitor is formed in a portion in which the cross-sectional line XV-XV′ is positioned.

Referring to FIG. 16, the boost capacitor of the comparative example is formed by overlapping the first scan line 151 positioned on the first conductive layer and the connecting portion C2C3 positioned on the semiconductor layer. Accordingly, only the first insulating film 141 exists between the first scan line 151 and the connecting portion C2C3 which is a semiconductor layer, so that the first scan line 151 and the connecting portion C2C3 are positioned with a second interval (gap2) therebetween.

Compared with the first gap (gap1) between the two electrodes of the boost capacitor of FIG. 13, it can be seen that the second gap (gap2) between the two electrodes of the boost capacitor of the comparative example is small, so the size of the boost capacitor is large in the comparative example. In addition, as a result of calculating the capacitance of the boost capacitor of FIG. 13 was 3.2f, and a result of calculating the capacitance of the boost capacitor of the comparative example was 4.8f, it can be seen that the capacitance was reduced by about 35%. Even in the comparative example, since the connecting portion C2C3 is connected to the gate electrode (not shown) of the driving transistor T1 by the connecting member SD123, the voltage of the gate electrode of the driving transistor Ti may be significantly affected by a large boost capacitor.

In addition, in the comparative example, one electrode of the boost capacitor is configured of the connecting portion C2C3 formed of an oxide semiconductor, and in the oxide semiconductor, a dispersion such as a width during a process is larger than that of a conductive layer and is not constant, so the size of the boost capacitor formed in each pixel may also vary.

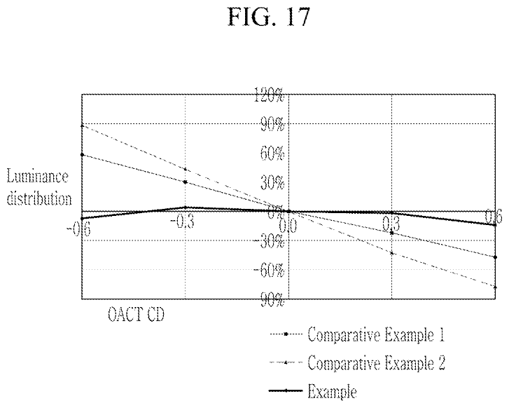

Since the display luminance is not constant due to the difference in the size of the boost capacitor for each pixel, luminance dispersion may occur, and hereinafter, the luminance distribution characteristics of the comparative example and the example will be compared and described with reference to FIG. 17.

FIG. 17 illustrates a graph comparing luminance distribution characteristics between comparative examples and an present embodiment.

FIG. 17 compares luminance distribution characteristics between two comparative examples (Comparative Example 1 and Comparative Example 2) and the present embodiment.

The present embodiment corresponds to FIGS. 3, 4, 5, 6, 7, 8, 9, 10, 11, and, 12, and Comparative Example 1 and Comparative Example 2 correspond to the structures of FIGS. 14 and 15, respectively, but values measured in a separate panel are shown.

In FIG. 17, an x-axis represents a relative size of a width (CD) of an oxide semiconductor (OACT), and a y-axis represents a difference in luminance displayed by the corresponding pixel.

In Comparative Example 1 and Comparative Example 2, it can be seen that as the width (CD) of the oxide semiconductor (OACT) is changed, the size of the boost capacitor is changed and the luminance displayed by the pixel is changed, so that the dispersion value is changed. Accordingly, when there is process dispersion as in the case of the oxide semiconductor, dispersion may accordingly occur in the luminance displayed by pixels, and this may be viewed as a spot.

However, in the present embodiment, it can be seen that even if the width (CD) of the oxide semiconductor (OACT) is changed, there is little change in the luminance displayed by the pixel because it is independent of the size of the boost capacitor. As a result, according to the present embodiment, deterioration of display quality such as bruising due to the boost capacitor may not occur.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A light emitting display device, comprising:
a driving transistor including a first gate electrode and a first semiconductor;
a second transistor including a second gate electrode, and a second semiconductor having one end connected to a data line and another end connected to the first gate electrode of the driving transistor;
a light emitting diode including an anode;
a storage capacitor including a first storage electrode connected to the anode of the light emitting diode and a second storage electrode overlapping the first storage electrode in a plan view;
a first scan line connected to the second gate electrode of the second transistor; and
a driving gate electrode connecting member connecting the second semiconductor of the second transistor, the second storage electrode, and the first gate electrode of the driving transistor,
wherein the first scan line and the driving gate electrode connecting member cross and overlap in a plan view, and
the first scan line and the driving gate electrode connecting member are positioned on a different layer from the first gate electrode, the second gate electrode, the first semiconductor, and the second semiconductor.

2. The light emitting display device of claim 1, wherein
the first scan line and the driving gate electrode connecting member cross and overlap in a plan view to configure a boost capacitor.

3. The light emitting display device of claim 1, further comprising
a hold capacitor including a first electrode and a second electrode,
wherein the second electrode of the hold capacitor is integral with the first storage electrode, and
the first electrode of the hold capacitor and the first storage electrode overlap in a plan view to configure the hold capacitor.

4. The light emitting display device of claim 3, wherein
the first electrode of the hold capacitor is connected to a driving voltage line or a reference voltage line.

5. The light emitting display device of claim 1, further comprising
a third transistor including a third gate electrode and a third semiconductor having one end connected to a reference voltage line and another end connected to the second semiconductor,
wherein the third semiconductor is connected to the second storage electrode and the first gate electrode of the driving transistor through the driving gate electrode connecting member.

6. The light emitting display device of claim 1, further comprising
a fourth transistor including a fourth gate electrode and a fourth semiconductor having one end connected to an initialization voltage line and another end connected to the first storage electrode of the storage capacitor.

7. The light emitting display device of claim 6, wherein
the initialization voltage line is an initialization voltage line for a green pixel or an initialization voltage line for a red or blue pixel.

8. The light emitting display device of claim 1, further comprising
a fifth transistor including a fifth gate electrode and a fifth semiconductor having one end connected to a driving voltage line and another end connected to the first semiconductor.

9. The light emitting display device of claim 8, further comprising
a shielding member extending from the fifth semiconductor and overlapping the data line,
wherein the shielding member is applied with a driving voltage.

10. The light emitting display device of claim 1, wherein
the first semiconductor of the driving transistor is integrally formed with the first storage electrode.

11. The light emitting display device of claim 1, wherein:
a first conductive layer including the first scan line and the second storage electrode is positioned on a substrate,
a first insulating film is positioned on the first conductive layer,
a semiconductor layer that includes the first semiconductor, the second semiconductor, and the first storage electrode and is formed of an oxide semiconductor, is positioned on the first insulating film,
a second insulating film is positioned on the semiconductor layer,
a second conductive layer including the first gate electrode and the second gate electrode is positioned on the second insulating film,
a third insulating film is positioned on the second conductive layer, and
a third conductive layer including the data line and the driving gate electrode connecting member is positioned on the third insulating film.

12. The light emitting display device of claim 1, wherein
the first gate electrode does not overlap the first storage electrode and the second storage electrode in a plan view.

13. A light emitting display device, comprising:
a driving transistor including a first gate electrode and a first semiconductor;
a second transistor including a second gate electrode, and a second semiconductor having one end connected to a data line and another end connected to the first gate electrode of the driving transistor;
a light emitting diode including an anode; and
a storage capacitor including a first storage electrode connected to the anode of the light emitting diode and a second storage electrode overlapping the first storage electrode in a plan view,
wherein the first gate electrode does not overlap the first storage electrode or the second storage electrode in a plan view.

14. The light emitting display device of claim 13, further comprising
a hold capacitor including a first electrode and a second electrode,
wherein the second electrode of the hold capacitor is integral with the first storage electrode,
the first electrode of the hold capacitor and the second storage electrode overlap in a plan view,
the first gate electrode does not overlap the first electrode of the hold capacitor in a plan view, and
the first electrode of the hold capacitor is connected to a driving voltage line or a reference voltage line.

15. The light emitting display device of claim 13, further comprising
a first scan line connected to the second gate electrode of the second transistor; and
a driving gate electrode connecting member connecting the second semiconductor of the second transistor, the second storage electrode, and the first gate electrode of the driving transistor,
wherein the first scan line and the driving gate electrode connecting member cross and overlap in a plan view, and
the first scan line and the driving gate electrode connecting member are positioned on a different layer from the first gate electrode, the second gate electrode, the first semiconductor, and the second semiconductor.

16. The light emitting display device of claim 15, further comprising
a third transistor including a third gate electrode and a third semiconductor having one end connected to a reference voltage line and another end connected to the second semiconductor,
wherein the third semiconductor is connected to the second storage electrode and the first gate electrode of the driving transistor through the driving gate electrode connecting member.

17. The light emitting display device of claim 13, further comprising
a fourth transistor including a fourth gate electrode, and a fourth semiconductor having one end connected to an initialization voltage line and another end connected to the first storage electrode of the storage capacitor.

18. The light emitting display device of claim 17, wherein
the initialization voltage line is an initialization voltage line for a green pixel or an initialization voltage line for a red or blue pixel.

19. The light emitting display device of claim 13, further comprising
a fifth transistor including a fifth gate electrode and a fifth semiconductor having one end connected to a driving voltage line and another end connected to the first semiconductor.

20. The light emitting display device of claim 19, further comprising
a shielding member extending from the fifth semiconductor and overlapping the data line,
wherein the shielding member is applied with a driving voltage.
